(19) United States
(12) Patent Application Publication
(10) Pub. No.: US 2010/0127738 A1
(43) Pub. Date: May 27, 2010

(54) CIRCUIT SYSTEM, CIRCUIT BLOCK, AND ELECTRONIC DEVICE

(75) Inventor: Katsuhiko Takeuchi, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/569,731

(22) Filed: Sep. 29, 2009

(30) Foreign Application Priority Data
Nov. 27, 2008 (JP) 2008-302486

(51) Int. Cl. H03L 7/00

(52) U.S. Cl. 327/143

(57) ABSTRACT

According to one embodiment, a circuit system includes an adjusted module, a circuit adjusting module, a power controller, and a set value storage module. The adjusted module operates in a circuit state adjusted by calibration. The circuit adjusting module adjusts the circuit state of the adjusted module by calibration and obtains a set value corresponding to the adjusted circuit state. The power controller stops power supply to at least the adjusted module upon transition to power saving mode and resume the power supply upon return from the power saving mode. The set value storage module non-volatilely stores the set value even in the power saving mode. The circuit adjusting module causes the set value storage module to non-volatilely store the set value upon power-on, and adjusts the circuit state of the adjusted module according to the set value upon return from the power saving mode.

### CROSS-REFERENCE TO RELATED APPLICATIONS

This application is based upon and claims the benefit of priority from Japanese Patent Application No. 2008-302486, filed on Nov. 27, 2008, the entire contents of which are incorporated herein by reference.

### BACKGROUND

1. Field

One embodiment of the invention relates to a circuit system, a circuit block, and an electronic device including a circuit portion circuit state of which is adjusted by calibration.

2. Description of the Related Art

For example, among analog-to-digital converters (ADCs), there are some whose precision is maintained by calibration before operation. Among time base generators (TBGs) for generating a clock having an arbitrary frequency from a fixed clock, there are some for which calibration is performed for assuring precision of the frequency of the generated clock. Like these examples, the precision of some circuits is assured by performing calibration before operation. For example, among circuits mounted on a magnetic disk device is a circuit block called read channel (RDC). RDC includes ADC and TBG and, to assure the precision, calibration is performed when power is turned on.

On the other hand, decrease in power consumption is demanded in various devices, typified by a magnetic disk device. To meet this demand, it is often the case that a device enters power saving mode when not in operation to stop power supply to unnecessary circuits.

When required to operate in the power saving mode, for example, when access to a magnetic disk medium becomes necessary in a magnetic disk device, the device enters normal operation mode. In this case, transition to the normal operation mode needs to be promptly performed not to cause a delay in processing.

In circuit blocks requiring calibration, such as RDC, however, if power supply is stopped in the power saving mode and then is resumed due to transition to the normal operation mode, calibration is required as an advance preparation before the normal operation is resumed. Therefore, the normal operation cannot be immediately performed, and a non-negligible time delay of, for example, hundreds of milliseconds occurs before the normal operation is resumed. Reference may be had to, for example, Japanese Patent Application Publication (KOKAI) No. 2003-209616.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary block diagram of the circuitry of a magnetic disk device as a comparative example;

FIG. 2 is an exemplary perspective view of a notebook personal computer (PC) as an example of an electronic device according to a first embodiment of the invention;

FIG. 3 is an exemplary view of a magnetic disk device built in the notebook PC illustrated in FIG. 2 in the first embodiment;

FIG. 4 is an exemplary block diagram of the inner circuitry of a system LSI mounted on the magnetic disk device illustrated in FIG. 3 in the first embodiment;

FIG. 5 is an exemplary block diagram of the circuitry related to calibration of a RDC in the RDC and an HDC each illustrated in one block in FIG. 4 in the first embodiment;

FIG. 6 is an exemplary flowchart of the operation upon initial power-on in the first embodiment;

FIG. 7 is an exemplary flowchart of the operation upon mode transition in the first embodiment;

FIG. 8 is an exemplary block diagram of the inner circuitry of a system LSI mounted on the magnetic disk device illustrated in FIG. 3 according to a second embodiment of the invention;

FIG. 9 is an exemplary block diagram of the circuitry relating to calibration of a RDC in the RDC and an HDC each illustrated in one block in FIG. 8;

FIG. 10 is an exemplary block diagram of the circuitry of the RDC according to a third embodiment of the invention.

### DETAILED DESCRIPTION

Various embodiments according to the invention will be described hereinafter with reference to the accompanying drawings. In general, according to one embodiment of the invention, a circuit system comprises an adjusted module, a circuit adjusting module, a power controller, and a set value storage module. The adjusted module is configured to operate in a circuit state adjusted by calibration. The circuit adjusting module is configured to adjust the circuit state of the adjusted module by calibration and obtain a set value according to the circuit state adjusted by the calibration. The power controller is configured to stop power supply to at least the adjusted module of the adjusted module and the circuit adjusting module upon transition to power saving mode and resume the power supply upon return from the power saving mode. The set value storage module is configured to non-volatilely store, even in the power saving mode, the set value obtained by the calibration of the adjusted module by the circuit adjusting module. The circuit adjusting module is configured to cause the set value storage module to non-volatilely store the set value obtained by the calibration of the adjusted module upon power-on, and adjust the circuit state of the adjusted module according to the set value stored in the set value storage module upon return from the power saving mode.

According to another embodiment of the invention, a circuit block is configured to perform calibration to adjust a circuit state and obtain a set value corresponding to the circuit state adjusted by the calibration, and operate in a circuit state according to the set value. The circuit block includes a set value storage module and a circuit adjusting module. The set value storage module is configured to store the set value obtained by the calibration. The circuit adjusting module is configured to perform calibration to obtain the set value and cause the set value storage module to store the set value upon power-on to the circuit block, and adjust the circuit state according to the set value stored in the set value storage module upon return from power saving mode. The circuit block includes a power-shutdown region to which power supply is shut down upon transition to the power saving mode and a power-non-shutdown region to which power supply continues in the power saving mode. The set value storage module is configured to store the set value in the power-non-shutdown region.

According to still another embodiment of the invention, a circuit block includes an analog circuit, and is configured to perform calibration to adjust a circuit state and obtain an analog set value corresponding to the circuit state adjusted by the calibration and operate in a circuit state according to the analog set value. The circuit block comprises an analog-to-digital converter, a digital-to-analog converter, and a circuit adjusting module. The analog-to-digital converter is configured to convert the analog set value obtained by the calibration to a digital set value. The digital-to-analog converter is configured to receive the digital set value and convert the digital set value to the analog set value. The circuit adjusting module is configured to perform calibration to obtain the analog set value, cause the analog-to-digital converter to convert the analog set value to the digital set value, and output the digital set value upon power-on to the circuit block. The circuit adjusting module is configured to receive the digital set value, cause the digital-to-analog converter to convert the digital set value to the analog set value, and adjust the circuit state according to the analog set value upon return from power saving mode.

According to still another embodiment of the invention, an electronic device comprises a circuit system. The circuit system comprises an adjusted module, a circuit adjusting module, a power controller, and a set value storage module. The adjusted module is configured to operate in a circuit state adjusted by calibration. The circuit adjusting module is configured to adjust the circuit state of the adjusted module by calibration and obtain a set value according to the circuit state adjusted by the calibration. The power controller is configured to stop power supply to at least the adjusted module of the adjusted module and the circuit adjusting module upon transition to power saving mode and resume the power supply upon return from the power saving mode. The set value storage module is configured to non-volatilely store, even in the power saving mode, the set value obtained by the calibration of the adjusted module by the circuit adjusting module. The circuit adjusting module is configured to cause the set value storage module to non-volatilely store the set value obtained by the calibration of the adjusted module upon power-on, and adjust the circuit state of the adjusted module according to the set value stored in the set value storage module upon return from the power saving mode.

First, a comparative example is described for comparison with the embodiments of the invention described later.

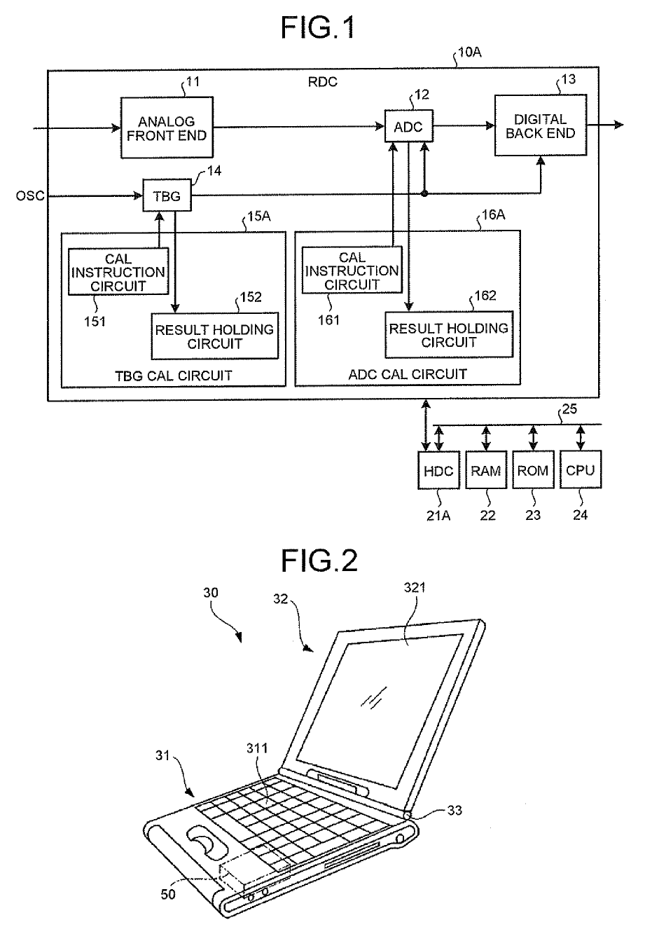

FIG. 1 is a block diagram of the circuitry of a magnetic disk device as the comparative example.

In FIG. 1, for RDC, i.e., a circuit block requiring calibration, the internal configuration of only part necessary for the description on calibration is illustrated, and for components other than the RDC, they are each illustrated in a circuit block.

As illustrated in FIG. 1, the magnetic disk device comprises a RDC 10A, an HDC 21A, a RAM 22, a ROM 23, and a CPU 24. In the RDC 10A, an analog signal picked up from, for example, a magnetic disk medium (not illustrated) is received by an analog front end 11, and is converted to digital data in an ADC 12. The digital data is then passed to a digital back end 13, where necessary digital processing is performed. The RDC 10A comprises a TBG 14 for receiving a fixed oscillator clock (OSC) and generating a clock for use in the ADC 12 and the digital back end 13.

The TBG 14 is a supply source of a clock used mainly in the ADC 12 and the digital back end 13. In the TBG 14, when a clock used in the ADC 12 and the digital back end 13 is generated from the fixed clock OSC, calibration is needed to assure the precision of the frequency of the generated clock. For this purpose, the RDC 10A comprises a TBG CAL circuit 15A for performing calibration of the TBG 14. The TBG CAL circuit 15A comprises a CAL instruction circuit 151 for instructing the TBG 14 of calibration, and a result holding circuit 152 in which a set value according to a circuit state of the TBG 14, which is the result of the calibration, is stored. In the TBG 14, calibration is performed at the instruction of the CAL instruction circuit 151 to adjust the circuit state. In the TBG 14, an analog set value representing the adjusted circuit state, that is, in this case, an analog set value corresponding to the frequency of a clock supplied to the ADC 12 and the digital back end 13 is generated, and the analog set value is stored in the result holding circuit 152.

The ADC 12 converts analog data output from the analog front end 11 to digital data that can be used in the digital back end 13. The ADC 12 requires precision. In addition, the ADC 12 needs to cover a wide band (typically, on the order from hundreds of megahertz to several gigahertz). Therefore, the ADC 12 also requires advance calibration.

For this requirement, the RDC 10A comprises an ADC CAL circuit 16A for performing calibration of the ADC 12. Like the TBG CAL circuit 15A, the ADC CAL circuit 16A comprises a CAL instruction circuit 161 and a result holding circuit 162. In the ADC 12, calibration is performed at the instruction of the CAL instruction circuit 161 to adjust the circuit state. In the ADC 12, an analog set value representing the adjusted circuit state, that is, in this case, an analog set value representing a reference voltage functioning as a reference for an analog-to-digital conversion process in the ADC 12 is generated. The analog set value is stored in the result holding circuit 162.

The RDC 10A operates at the instruction of an HDC 21A to be described hereinbelow, and transmits data processed in the digital back end 13 to the HDC 21A.

The HDC 21A illustrated in FIG. 1 communicates with a host(not illustrated) to receive an instruction from the host and data to be written in a magnetic disk medium (not illustrated), and transmit data read from a magnetic disk medium to the host. The RAM 22 is a kind of volatile memory and is used as a buffer or the like for temporarily storing data. The ROM 23 is a read-only, nonvolatile memory, and various kinds of programs, fixed values and the like are stored therein. The CPU 24 executes programs to control the overall operation of the circuit system.

The HDC 21A, the RAM 22, the ROM 23, and the CPU 24 are mutually connected via a bus 25.

It is assumed herein that power saving mode is applied to the RDC 10A. In the power saving mode, power supply to the RDC 10A is stopped. Upon transition from the power saving mode to a normal operation mode, power supply to the RDC 10A is resumed. Upon transition to the normal operation mode, first, calibration is performed in the RDC 10A to adjust the circuit states of the ADC 12 and the TBG 14. It takes hundreds of milliseconds for this adjustment. In this manner, there is a time lag until the RDC 10A normally starts its operation. This results in a delay in return of the entire circuit system from the power saving mode.

Based on the comparative example of FIG. 1, a first embodiment of the invention is described hereinbelow.

FIG. 2 is a perspective view of a notebook PC 30 as an example of an electronic device according to the first embodiment.

The notebook PC 30 comprises a main body 31 and a display module 32. The display module 32 is joined to the main body 31 with a hinge 33 in an openable/closable manner.

The main body 31 has a keyboard 311 on its top surface, and has a CPU (not illustrated), a magnetic disk device 50, and the like therein. The display module 32 is provided with a display screen 321. The configuration of the notebook PC 30 is widely known, and thus further detailed description on the notebook PC itself is omitted.

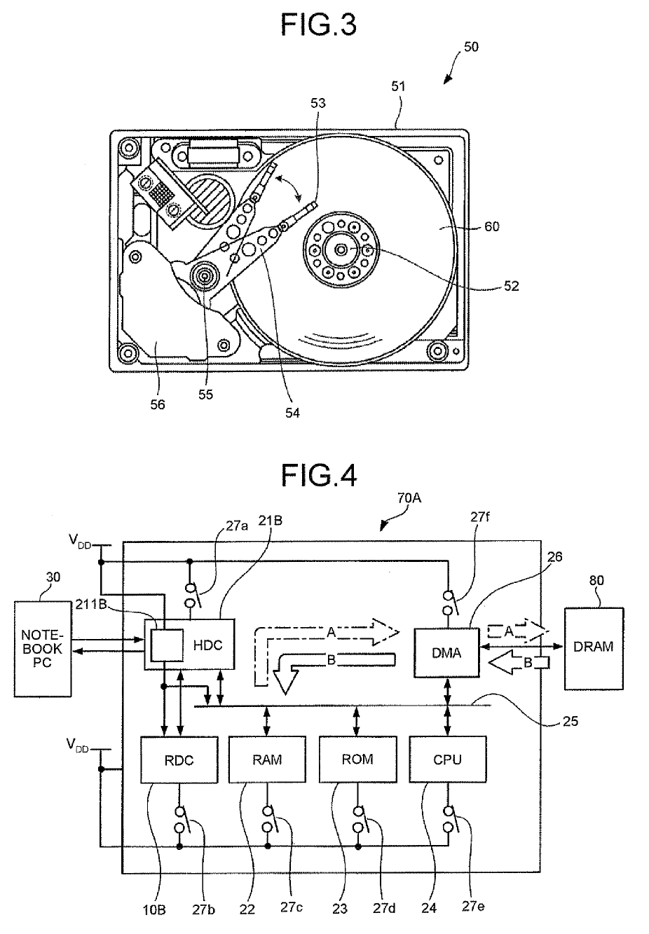

FIG. 3 illustrates a magnetic disk device 50 built in the notebook PC 30.

The magnetic disk device 50 also is an example of the electronic device.

As illustrated in FIG. 3, the magnetic disk device 50 comprises a magnetic disk medium 60 rotating about a rotating shaft 52 inside a housing 51. An arm 54 holding a magnetic head 53 at its tip is also provided inside the housing 51. The magnetic head 53 performs information recording and information reproducing on and from the magnetic disk medium 60. The arm 54, fixed to an arm shaft 55, rotates about the arm shaft 55 along the surface of the magnetic disk medium 60. The arm shaft 55 is driven by a voice coil motor 56.

In recording and reproducing information on and from the magnetic disk medium 60, the arm 54 is driven by the voice coil motor 56, so that the magnetic head 53 is positioned above the rotating magnetic disk medium 60. In recording of information, an electrical recording signal is input to the magnetic head 53, and a magnetic field according to the recording signal is applied by the magnetic head 53 to record information carried by the recording signal on the magnetic disk medium 60. In reproducing of information, information magnetically recorded on the magnetic disk medium 60 is extracted as an electrical reproduced signal by the magnetic head 53.

FIG. 4 is a block diagram of the inner circuitry of a system LSI mounted on the magnetic disk device 50 illustrated in FIG. 3. In FIG. 4, circuit blocks, etc. having the same actions as those of circuit blocks, etc. illustrated in FIG. 1 are denoted by the same reference numerals.

A system LSI 70A comprises a RDC 10B, an HDC 21B, a RAM 22, a ROM 23, a CPU 24 and a DMA 26.

The HDC 21B transfers communication between the notebook PC 30 (see FIG. 2) serving as a host and the system LSI 70A. The HDC 21B is connected to a power supply V_{DD} through a switching element 27a. However, power is supplied directly from the power supply V_{DD} without passing through any switching element to a circuit region 211B, which is a part of the HDC 21B and in which a communication interface with the notebook PC 30 is placed.

The RDC 10B, the RAM 22, the ROM 23, the CPU 24, and the DMA 26 are connected to the power supply V_{DD} through switching elements 27b, 27c, 27d, 27e, and 27f, respectively. The RDC 10B differs from the RDC 10A illustrated in FIG. 1 in circuit portions relevant to calibration and the like; however, actions in the normal operation of the RDC 10B are the same as those of the RDC 10A illustrated in FIG. 1. The differences will be described later. The RAM 22, the ROM 23, and the CPU 24 are the same as those illustrated in FIG. 1.

The DMA 26, together with the HDC 21B, the RAM 22, the ROM 23, and the CPU 24, is connected to the bus 25.

In transition to the power saving mode, the switching elements 27a to 27f are disconnected, so that power supplied from the power supply V_{DD} is shut down. The DMA 26 has a role of saving various kinds of data stored in the RAM 22 to a DRAM 80 placed outside the system LSI 70A without any operation of the CPU 24 before the power supply is shut down (indicated by arrows A in FIG. 4). The DMA 26 also has a role of writing back the various kinds of data saved in the DRAM 80 to the RAM 22 without any operation of the CPU 24 upon return from the power saving mode (indicated by arrows B in FIG. 4).

The CPU 24 is in charge of disconnecting each of the switching elements 27a to 27f. The CPU 24 disconnects the switching elements 27a to 27d and 27f other than the switching element 27e, and thereafter disconnects its own switching element 27e. In connecting the switching elements 27a to 27f, the circuit portion 211B, to which power is supplied continuously even in the power saving mode, in the HDC 21B is in charge of connection of the switching element 27e. The CPU 24 is in charge of connection of the other switching elements 27a to 27d and 27f. In other words, the HDC 21B receives an instruction from the notebook PC 30 and establishes connection of the switching element 27e to supply power to the CPU 24, and further transmits an interrupt signal to the CPU 24. Then, the CPU 24 establishes connection of the other switching elements 27a to 27d and 27f.

Even in the power saving mode, power is continuously supplied to the circuit region 211B in the HDC 21B, in which a communication interface having a role of communication with the notebook PC 30 is placed. Accordingly, the HDC 21B can receive an instruction from the notebook PC 30. When the HDC 21B receives an instruction from the notebook PC 30, connection of each of the switching elements 27a to 27f is established to supply power to each circuit block. Thus, transition from the power saving mode to the normal operation mode is performed.

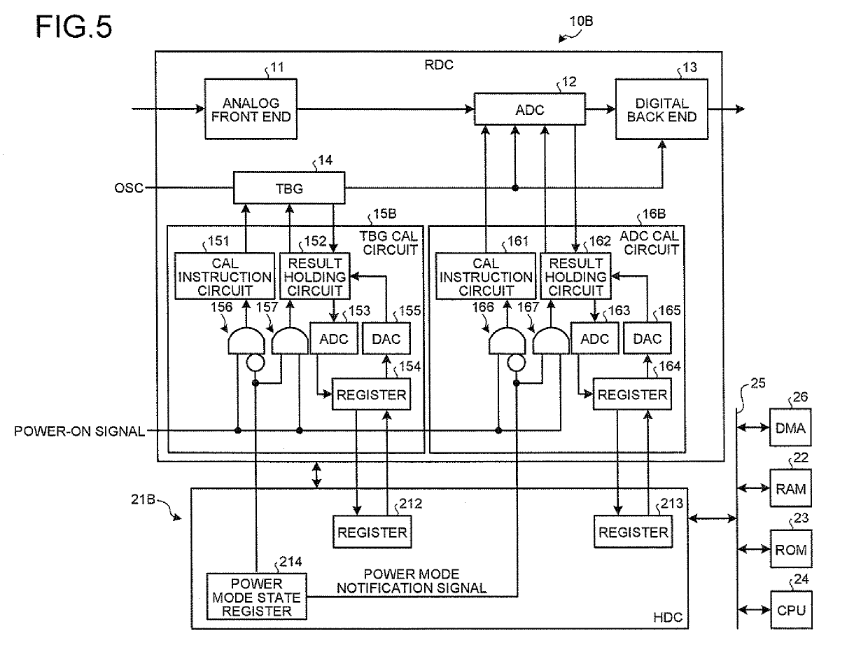

FIG. 5 is a block diagram of the circuitry related to calibration of the RDC 10B in the RDC 10B and the HDC 21B each illustrated in one block in FIG. 4.

The circuit diagram of FIG. 5 is to be compared with FIG. 1 as a comparative example, and differences from FIG. 1 are described.

A TBG CAL circuit 15B of the RDC 10B illustrated in FIG. 5 comprises an AD converter 153, a register 154, and a DA converter 155. The AD converter 153 converts an analog set value, which results from calibration of the TBG 14 and is stored in the result holding circuit 152, to a digital set value. The digital set value obtained by the conversion is temporarily stored in the register 154.

Corresponding to the register 154, a register 212 is provided in the HDC 21B. The digital set value stored in the register 154 is transmitted to the HDC 21B, and is stored in the register 212 of the HDC 21B. The register 212 is placed in the circuit region 211B (see FIG. 4), to which power from the power supply V_{DD} is supplied continuously even in the power saving mode, in the HDC 21B. In returning from the power saving mode to the normal operation mode, after power supply to the RDC 10B is resumed, the digital set value stored in the register 212 of the HDC 21B is transmitted to the RDC 10B, and is written back to the register 154 placed in the TBG CAL circuit 15B. The digital set value written back to the register 154 is, in turn, converted to an analog set value by the DA converter 155 provided in the TBG CAL circuit 15B, and is stored in the result holding circuit 152.

These configurations are the same as in an ADC CAL circuit 16B. That is, the ADC CAL circuit 16B comprises an AD converter 163, a register 164, and a DA converter 165.

The AD converter 163 converts an analog set value required for calibration of the ADC 12 to a digital set value. The digital set value obtained by the conversion is temporarily stored in the register 164.

Corresponding to the register 164, a register 213 is provided in the HDC 21B. The digital set value stored in the register 164 is transmitted to the HDC 21B, and is stored in the register 213 of the HDC 21B. The register 213 is placed in the circuit region 211B (see FIG. 4), to which power from the power supply V_{DD} is supplied continuously even in the power saving mode, in the HDC 21B. In returning from the power saving mode to the normal operation mode, after power supply to the RDC 10B is resumed, the digital set value stored in the register 213 of the HDC 21B is transmitted to the RDC 10B, and is written back to the register 164 placed in the ADC CAL circuit 16B. The digital set value written back to the register 164 is, in turn, converted to an analog set value by the DA converter 165 provided in the ADC CAL circuit 16B, and is stored in the result holding circuit 162.

At this point, when power is turned on in the RDC 10B, a power-on signal is generated in the RDC 10B. The generated power-on signal is supplied to the TBG CAL circuit 15B and the ADC CAL circuit 16B.

The power-on signal is generated each time power is turned on in the RDC 10B. In other words, the power-on signal is also generated at the timing (upon power-on) at which, from the condition that the entire system LSI 70A illustrated in FIG. 4 is separated from power supply, power is turned on in the entire system LSI 70A and power is initially turned on in the RDC 10B. The power-on signal is also generated at the timing at which the RDC 10B transits from the power saving mode to the normal operation mode by the change of the switching element 27a from its off-state to its on-state. Here, the power-on signal is a signal at a level ‘1’.

The HDC 21B is provided with a power mode state register 214. The power mode state register 214 is placed in the circuit region 211B (see FIG. 4), to which power is supplied continuously even in the power saving mode, in the HDC 21B.

The power mode state register 214 is initially set to ‘0’ when power is initially turned on in the entire system LSI 70A illustrated in FIG. 4 (upon power-on). Then, ‘1’ is written to the power mode state register 214 by the CPU 24 (see FIG. 4) when calibration of the RDC 10B is completed. The initially set signal ‘0’ and the subsequently written signal ‘1’ in the power mode state register 214 are input as power mode notification signals to the TBG CAL circuit 15B and the ADC CAL circuit 16B of the RDC 10B.

A power-on signal ‘1’ is generated when power is turned on in the RDC 10B, and a power mode signal ‘0’ representing initial power-on is output from the power mode state register 214. Then, signals ‘1’ for instructing to perform calibration are output from gate circuits 156 and 166 to the CAL instruction circuits 151 and 161. In response to the signals, the CAL instruction circuits 151 and 161 instruct the TBG 14 and the ADC 12 to perform calibration. In each of the TBG 14 and the ADC 12, the circuit state is adjusted by the calibration, and an analog set value representing the circuit state is stored in each of the result holding circuits 152 and 162. The subsequent circuit operation is as described above.

When a power-on signal ‘1’ is generated under the condition where ‘1’ is stored in the power mode state register 214, signals ‘1’ are output from the other gate circuits 157 and 167. The signals ‘1’ instruct that the circuit states of the TBG 14 and the ADC 12 should be adjusted using analog set values stored in the result holding circuits 152 and 162, respectively. In the result holding circuits 152 and 162, as described above, digital set values saved to the registers 212 and 213 of the HDC 21B pass through the registers 154 and 164 and are converted to analog set values in the DA converters 155 and 165, so that the analog set values are written back. The result holding circuits 152 and 162 pass the analog set values written back in this way to the TBG 14 and the ADC 12. The TBG 14 and the ADC 12 adjust the circuit states according to the analog set values received from the result holding circuits 152 and 162.

A time on the order of hundreds of milliseconds is required for calibration in the TBG 14 and the ADC 12. In contrast, adjustment of the circuit states using analog set values stored in the result holding circuits 152 and 162 takes a time on the order of only tens of nanoseconds. The circuit states are adjusted at an extremely high speed as compared to the case of performing calibration. This enables a high-speed transition from the power saving mode to the normal operation mode to be achieved.

In the first embodiment, the TBG 14 and the ADC 12 constitute one example of an adjusted module, the circuit state of which is adjusted by calibration, and which operates in the adjusted circuit state. The TBG 14 and the ADC 12 constitute one example of an adjusted module including an analog circuit. The TBG CAL circuit 15B and the ADC CAL circuit 16B constitute one example of a circuit adjusting module that causes the adjusted module to perform calibration to adjust the circuit state, thereby obtaining a set value according to the adjusted circuit state. The TBG CAL circuit 15B and the ADC CAL circuit 16B obtain analog set values by calibration of the TBG 14 and the ADC 12.

The registers 212 and 213 provided in the HDC 21B constitute one example of a set value storage module that non-volatilely stores, even in the power saving mode, a set value obtained by calibration of the adjusted module by the circuit adjusting module.

The switching element 27b illustrated in FIG. 4 and a circuit portion for turning on/off the switching element 27b in the HDC 21B constitute one example of a power controller that stops power supply to at least the adjusted module of the adjusted module and the circuit adjusting module (to both the adjusted module and the circuit adjusting module in the first embodiment) upon transition to the power saving mode and resumes it upon return from the power saving mode.

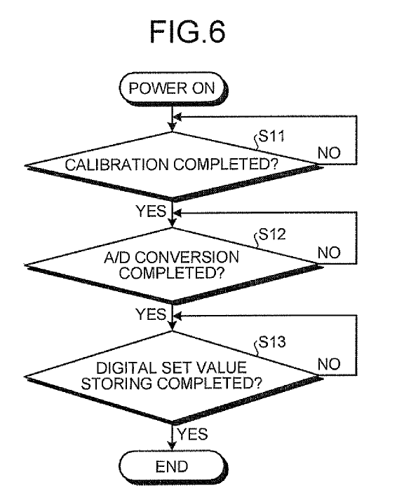

FIG. 6 is a flowchart of the operation upon initial power-on according to the first embodiment.

Upon power-on, calibration of the TBG 14 and the ADC 12 is performed as described above (S11), analog set values obtained by the calibration are converted to digital set values (S12), and digital set values obtained by the conversion are stored in the registers 212 and 213 of the HDC 21B (S13).

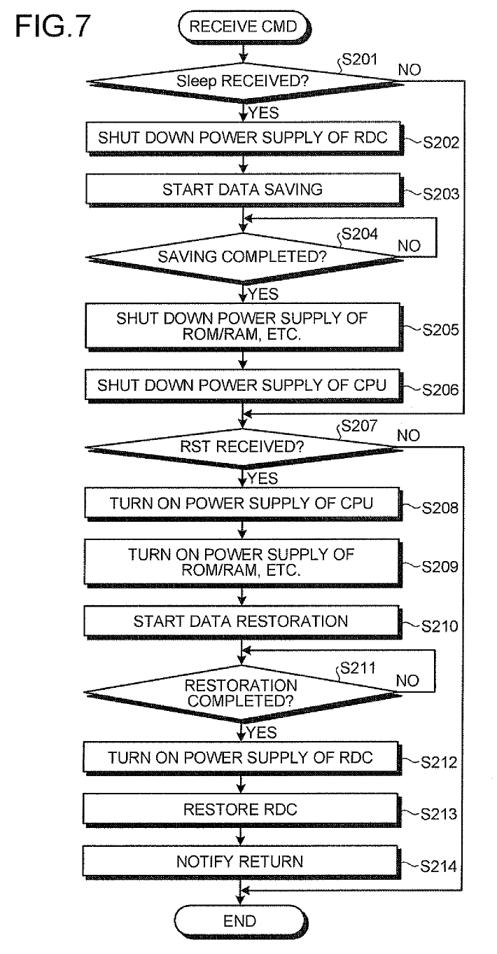

FIG. 7 is a flowchart of the operation upon mode transition according to the first embodiment.

FIG. 7 represents a process performed upon receiving a command (CMD). Here, only a sleep command (Sleep) and a reset command (RST) are covered. The sleep command (Sleep) is a command for instructing transition to the power saving mode. The reset command (RST) is a command for instructing transition from the power saving mode to the normal operation mode.

When a command (CMD) is received, it is determined whether or not the received command is a sleep command (Sleep) (S201). If the received command is not the sleep command (Sleep), then it is determined whether or not the received command is a reset command (RST) (S207). If the received command is neither of the two kinds of commands, then the process moves to another process (not illustrated in FIG. 7).

If the command received this time is a sleep command (Sleep), then the process proceeds to S202, where, by disconnecting first the switching element 27b illustrated in FIG. 4, power supply to the RDC 10B (see FIG. 5) is shut down.

Note that a set value obtained by calibration of the RDC 10B is saved when power supply is initially turned on (see FIG. 6). Next, data stored in the RAM 22 is saved to the DRAM 80 by the DMA 26 (S203). When saving of data is completed (S204), power supply to the HDC 21B (except part of it), the RAM 22, the ROM 23, and the DMA 26 is shut down by disconnecting the switching elements 27a, 27c, 27d, and 27f, respectively. Finally, by disconnecting the switching element 27e, power supply to the CPU itself is shut down (S206). Thus, transition to the power saving mode is completed.

When the reset command (RST) is received (S207), power supply to the CPU 24 is turned on (S208), and subsequently power supply to the HDC 21B, the RAM 22, the ROM 23, and the DMA 26 is turned on (S209).

Then, data saved to the DRAM 80 is written back to the RAM 22 by the DMA 26 (S210). When the write-back of the data (restoration of the data) is completed (S211), power supply to the RDC 10B is turned on (S212) , and the RDC 10B is restored (S213). In the restoration of the RDC 10B, the circuit states of the TBG 14 and the ADC 12 are adjusted based on digital set values saved to the registers 212 and 213 of the HDC 21B illustrated in FIG. 5. When the restoration of the RDC 10B is completed, return to the normal operation mode is notified from the HDC 21B to the notebook PC 30 (S214).

Next, a second embodiment of the invention is described.

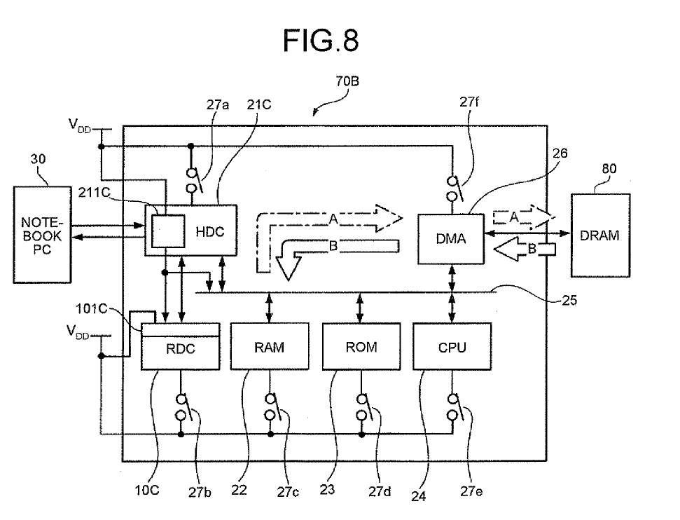

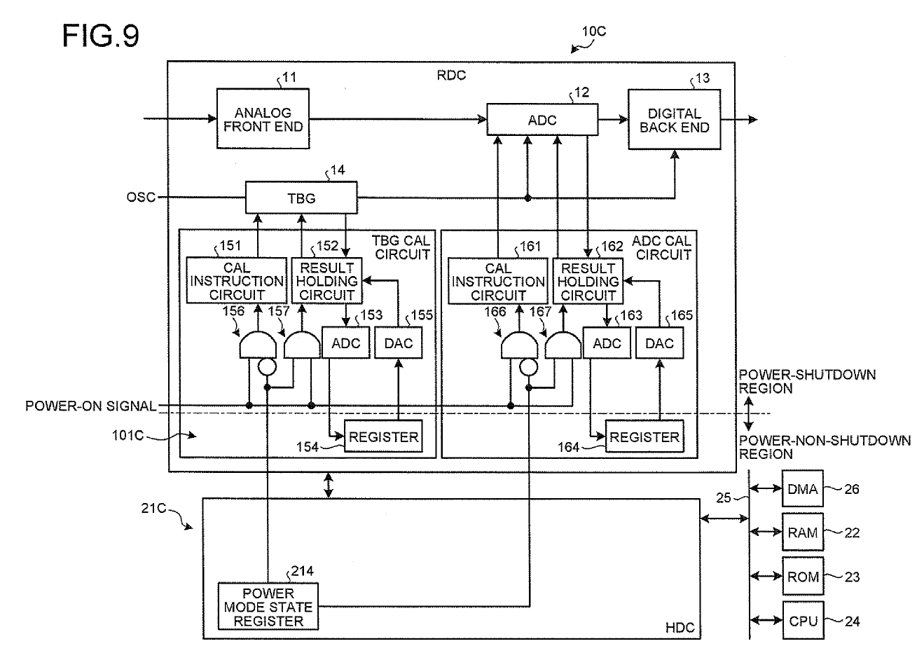

FIG. 8 is a block diagram of the inner circuitry of a system LSI 70B mounted in place of the system LSI 70A illustrated in FIG. 4 on the magnetic disk device 50 illustrated in FIG. 3. FIG. 9 is a block diagram of the circuitry relating to calibration of a RDC 10C in the RDC 10C and an HDC 21C each illustrated in one block in FIG. 8. FIG. 9 corresponds to FIG. 5 of the first embodiment. Elements in FIGS. 8 and 9 corresponding to those in FIGS. 4 and 5 are denoted by the same reference numerals, and the same description is not repeated.

Like the HDC 21B illustrated in FIG. 4, the HDC 21C constituting the system LSI 70B illustrated in FIG. 8 has a power-non-shutdown region 211C to which power is supplied continuously even in the power saving mode. However, the power-non-shutdown region 211C is not provided with registers (registers corresponding to the registers 212 and 213 of FIG. 5) for saving set values generated by calibration in the RDC 10C. All other respects of the HDC 21C are the same as those of the HDC 21B of FIGS. 4 and 5.

Unlike the RDC 10B of FIG. 4, the RDC 10C of FIG. 8 has a power-non-shutdown region 101C to which power is supplied continuously in the power saving mode.

As illustrated in FIG. 9, the registers 154 and 164 for storing digital set values obtained in the AD converters 153 and 163 are placed in the power-non-shutdown region 101C, to which power is supplied continuously even in the power saving mode, in the RDC 10C. Accordingly, the digital set values are not transmitted nor received between the RDC 10C and the HDC 21C. All other respects of the RDC 10C are the same as those of the RDC 10B of FIGS. 4 and 5.

All other respects of the system LSI 70B illustrated in FIG. 8 are basically the same as those of the system LSI 70A of FIG. 4.

According to the second embodiment illustrated in FIGS. 8 and 9, digital set values are non-volatilely stored inside the RDC 10C.

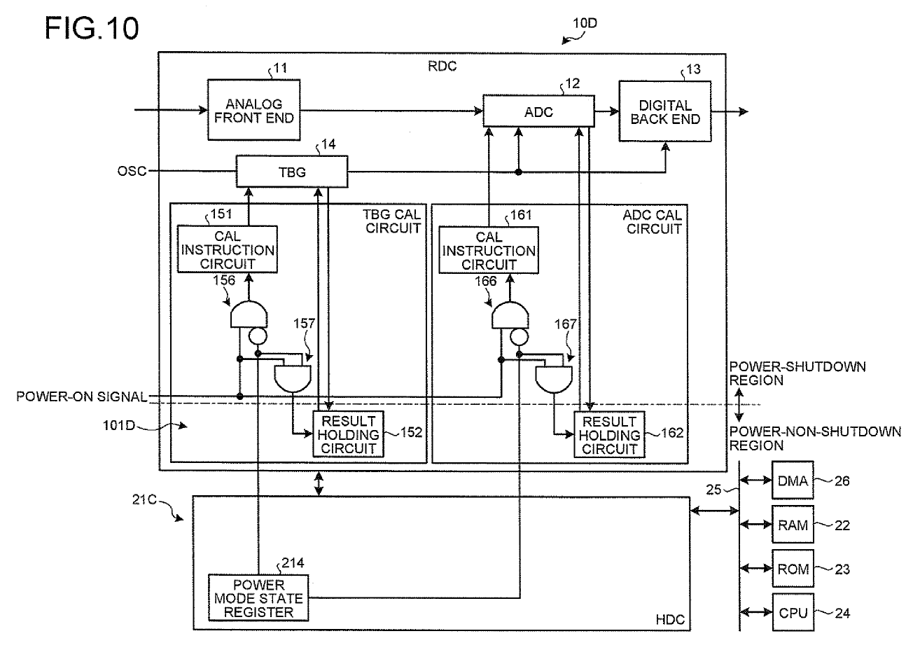

FIG. 10 is a block diagram of the circuitry of the RDC according to a third embodiment of the invention. In the third embodiment, the same elements as those in the first and second embodiments are denoted by the same reference numerals, and the same description is not repeated. In the following, the differences are described in comparison with the RDC 10C illustrated in FIG. 9.

Like the RDC 10C illustrated in FIG. 9, a RDC 10D illustrated in FIG. 10 has a power-non-shutdown region 101D to which power is supplied continuously even in the power saving mode. The result holding circuits 152 and 162 are placed in the power-non-shutdown region. That is, in the case of the RDC 10D illustrated in FIG. 10, analog set values remain unchanged and are stored non-volatilely. Accordingly, while the AD converters 153 and 163, the registers 154 and 164, and the DA converters 155 and 165 are provided to the RDC 10C illustrated in FIG. 9, they are not provided to the RDC 10D of FIG. 10.

Next, a fourth embodiment of the invention is described. The fourth embodiment is described referring again to FIG. 4.

Upon power-on, calibration is performed in the RDC 10B, and analog set values are generated. The analog set values are converted to digital set values and stored in the RAM 22 in the fourth embodiment. Upon transition to the power saving mode, power supply of the RAM 22 is also shut down. Before the shut-down, data (including the digital set values) in the RAM 22 is saved to the DRAM 80 by the DMA 26. Upon return from the power saving mode to the normal operation mode, the data (including the digital set values) saved to the DRAM 80 is written back to the RAM 22 by the DMA 26. Then the digital set values are written back from the RAM 22 to the RDC 10B. The subsequent restoration operation is the same as described above.

As in the fourth embodiment, data to be saved is stored in the RAM 22, and upon transition to the power saving mode, the data may be saved together with other data to the DRAM 80 at one time.

As set forth hereinabove, according to an embodiment of the invention, the circuit state of a circuit portion circuit state of which is adjusted by calibration can be adjusted at a high speed upon return from the power-saving mode. Accordingly, transition to the normal operation mode can be promptly performed, and processing can be promptly started.

While the embodiments have been described as being applied to circuits constituting a magnetic disk device mounted on a notebook PC, the embodiments are applicable not only to a notebook PC or a magnetic disk device but also to any electronic device on which a circuit including a circuit portion requiring adjustment by calibration is mounted.

The various modules of the systems described herein can be implemented as software applications, hardware and/or software modules, or components on one or more computers, such as servers. While the various modules are illustrated separately, they may share some or all of the same underlying logic or code.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A circuit system comprising:
an adjusted module configured to operate in a circuit state adjusted by calibration;
a circuit adjusting module configured to adjust the circuit state of the adjusted module by calibration and obtain a set value according to the circuit state adjusted by the calibration;
a power controller configured to stop power supply to at least the adjusted module of the adjusted module and the circuit adjusting module upon transition to power saving mode and resume the power supply upon return from the power saving mode; and
a set value storage module configured to non-volatilely store, even in the power saving mode, the set value obtained by the calibration of the adjusted module by the circuit adjusting module, wherein
the circuit adjusting module is configured to cause the set value storage module to non-volatilely store the set value obtained by the calibration of the adjusted module upon power-on, and adjust the circuit state of the adjusted module according to the set value stored in the set value storage module upon return from the power saving mode.

2. The circuit system of claim 1, wherein
the adjusted module comprises an analog circuit,
the circuit adjusting module is configured to obtain an analog set value by the calibration of the adjusted module,
the set value storage module is configured to store a digital set value obtained by converting the analog set value to digital data, and
the circuit adjusting module comprises
an analog-to-digital converter configured to convert the analog set value obtained by the calibration of the adjusted module to the digital set value, and
a digital-to-analog converter configured to convert the digital set value received from the set value storage module to the analog set value.

3. The circuit system of claim 1, wherein the set value storage module is configured to store the set value in a circuit region to which power is supplied even after transition to the power saving mode.

4. The circuit system of claim 2, further comprising a nonvolatile memory, wherein
the set value storage module is configured to store the set value in the nonvolatile memory.

5. The circuit system of claim 2, further comprising:
a volatile memory power supply to which is stopped upon transition to the power saving mode, wherein the set value storage module is configured to store the set value in the volatile memory;
a data saving memory configured to non-volatilely store data; and
a data transfer module configured to save data in the volatile memory to the data saving memory upon transition to the power saving mode and return the data in the data saving memory to the volatile memory upon return from the power saving mode.

6. A circuit block configured to perform calibration to adjust a circuit state and obtain a set value corresponding to the circuit state adjusted by the calibration, and operate in a circuit state according to the set value, the circuit block comprising:
a set value storage module configured to store the set value obtained by the calibration; and
a circuit adjusting module configured to perform calibration to obtain the set value and cause the set value storage module to store the set value upon power-on to the circuit block, and adjust the circuit state according to the set value stored in the set value storage module upon return from power saving mode, wherein
the circuit block includes a power-shutdown region to which power supply is shut down upon transition to the power saving mode and a power-non-shutdown region to which power supply continues in the power saving mode, and
the set value storage module is configured to store the set value in the power-non-shutdown region.

7. A circuit block including an analog circuit and configured to perform calibration to adjust a circuit state and obtain an analog set value corresponding to the circuit state adjusted by the calibration, and operate in a circuit state according to the analog set value, the circuit block comprising:
an analog-to-digital converter configured to convert the analog set value obtained by the calibration to a digital set value;
a digital-to-analog converter configured to receive the digital set value and convert the digital set value to the analog set value; and
a circuit adjusting module configured to perform calibration to obtain the analog set value, cause the analog-to-digital converter to convert the analog set value to the digital set value, and output the digital set value upon power-on to the circuit block, and receive the digital set value, cause the digital-to-analog converter to convert the digital set value to the analog set value, and adjust the circuit state according to the analog set value upon return from power saving mode.

8. An electronic device comprising a circuit system, the circuit system including
an adjusted module configured to operate in a circuit state adjusted by calibration;
a circuit adjusting module configured to adjust the circuit state of the adjusted module by calibration and obtain a set value according to the circuit state adjusted by the calibration;
a power controller configured to stop power supply to at least the adjusted module of the adjusted module and the circuit adjusting module upon transition to power saving mode and resume the power supply upon return from the power saving mode; and
a set value storage module configured to non-volatilely store, even in the power saving mode, the set value obtained by the calibration of the adjusted module by the circuit adjusting module, wherein
the circuit adjusting module is configured to cause the set value storage module to non-volatilely store the set value obtained by the calibration of the adjusted module upon power-on, and adjust the circuit state of the adjusted module according to the set value stored in the set value storage module upon return from the power saving mode.
